(19) United States
(12) Patent Application Publication
(10) Pub. No.: US 2016/0149101 A1
(43) Pub. Date: May 26, 2016

(54) OPTOELECTRONIC SEMICONDUCTOR COMPONENT

(71) Applicant: OSRAM Opto Semiconductors GmbH, Regensburg (DE)

(72) Inventors: Frank SINGER, Regenstauf (DE); Wolfgang MOENCH, Pentling (DE); Alexander LINKOV, Regensburg (DE)

(73) Assignee: OSRAM Opto Semicouductors GmbH, Regensburg (DE)

(21) Appl. No.: 14/900,144

(22) PCT Filed: Jun. 25, 2014
(86) PCT No.: PCT/EP2014/063403

§ 371 Date: Dec. 18, 2015

(30) Foreign Application Priority Data
Jun. 26, 2013 (DE) 102013106689.5

(51) Int. Cl. H01L 33/60; H01L 33/50; H01S 5/022; H01L 33/48

(52) U.S. Cl. CPC H01L 33/60; H01L 33/486; H01L 33/502; H01S 5/02236; H01S 5/0228; H01L 2933/0091

(57) ABSTRACT

In at least one embodiment, the optoelectronic semiconductor component (1) comprises a cast body (4). At least one optoelectronic semiconductor chip (3) is designed to generate radiation and is situated in a recess (43) in the cast body (4). The semiconductor chip (3) has a main radiation side (30) having an edge length (L). At least one lens plate (5), which covers the recess (43), is arranged downstream of the semiconductor chip (1) in a main radiation direction (M). The lens plate (5) has a plurality of structural elements (55) on an upper side (50) that faces away from the semiconductor chip (1). The lens plate (5) has a diameter (D) that is at least 1.5 times the edge length (L). A thickness (H) of the lens plate (5) is at least 0.1 times and at most 1.5 times the diameter (D). The lens plate (5) covers the main radiation side (30) completely.

An optoelectronic semiconductor component is provided.

An object to be achieved is to provide an optoelectronic semiconductor component which displays an emission pattern with a high proportion of radiation at large angles.

This object is achieved inter alia by an optoelectronic semiconductor component having the features of the independent claim. Preferred further developments constitute the subject matter of the dependent claims.

According to at least one embodiment, the semiconductor component comprises one or more potting bodies. It is possible for the potting body to form the component mechanically bearing and supporting the semiconductor component. In this case the semiconductor component is not mechanically robust without the potting body. The potting body is produced for example by casting, molding or transfer molding. The potting body is preferably non-transmissive to radiation emitted by the semiconductor component when in operation.

According to at least one embodiment, the potting body comprises a recess. When viewed in plan view, the potting body preferably surrounds the recess. It is possible for the recess to pass right through the potting body.

According to at least one embodiment, the semiconductor component comprises one or more optoelectronic semiconductor chips, which are provided to generate radiation. In particular, the optoelectronic semiconductor chip is a light-emitting diode or a laser diode. If the semiconductor component comprises a plurality of optoelectronic semiconductor chips, these may be of like or indeed different construction and for instance emit in different spectral ranges. Preferably, at least one of the semiconductor chips or all the semiconductor chips emit blue light, in particular with a maximum intensity wavelength, or peak wavelength, of between 420 nm and 490 nm inclusive.

According to at least one embodiment, the semiconductor chip or the semiconductor chips is/are located in the recess in the potting body. If a plurality of semiconductor chips are present, all the semiconductor chips may be mounted together in a single recess or in each case precisely one recess may be provided for each semiconductor chip.

According to at least one embodiment, the semiconductor chips each have an edge length, when viewed in plan view onto a main radiation side. The edge length is for example at least 150 μm or 500 μm or 750 μm and/or at most 2.5 mm or 2 mm or 1.5 mm. When viewed in plan view, the semiconductor chip preferably has a square or rectangular basic shape and/or main radiation side.

According to at least one embodiment, the semiconductor component comprises one or more optical plates. The at least one optical plate covers the recess completely or in part. The optical plate is arranged downstream of the semiconductor chip in a main emission direction. The optical plate is transmissive to at least part of the radiation generated by the semiconductor component when in operation. In particular, it is possible for all the radiation generated during operation and leaving the semiconductor component to pass through the optical plate prior to exit from the semiconductor component.

According to at least one embodiment, the optical plate comprises a multiplicity of pattern elements on a top remote from the semiconductor chip. The pattern elements are for instance holes or depressions in the top and/or raised elements on the top. The pattern elements may be shaped from a base member for the optical plate or be applied to a base member, for instance by printing or vapor deposition. The pattern elements and the base member of the optical plate may consist of the same material or of different materials.

According to at least one embodiment, the optical plate, when viewed in plan view, has a diameter which corresponds to at least the edge length or at least 1.5 times or at least twice the edge length of the semiconductor chip. Alternatively or in addition, the diameter of the optical plate is at most 15 times or ten times or seven times the edge length.

According to at least one embodiment, the optical plate has a thickness or an average thickness which amounts to at least 0.07 times or 0.1 times or 0.25 times and/or at most 2.5 times or 1.5 times the diameter of the optical plate. In other words, the optical plate is relatively thick compared with the diameter. In particular, the optical plate is mechanically self-supporting and produced separately from the further components of the semiconductor component.

According to at least one embodiment, the optical plate completely covers the main radiation side when viewed in plan view. The optical plate in this case preferably does not have any openings which pass completely through the optical plate. When viewed in plan view, the semiconductor chip is then only visible or accessible through a material of the optical plate.

In at least one embodiment, the optoelectronic semiconductor component comprises a potting body with at least one recess. At least one optoelectronic semiconductor chip is configured to generate radiation and is located in the recess. The semiconductor chip comprises a main radiation side with an edge length. At least one optical plate covering the recess is arranged downstream of the semiconductor chip in a main emission direction. At a top remote from the semiconductor chip, the optical plate comprises a multiplicity of pattern elements. The optical plate has a diameter which amounts to at least 1.5 times the edge length of the semiconductor chip. A thickness of the optical plate is at least 0.1 times and at most 1.5 times the diameter of the optical plate. The optical plate completely covers the main radiation side when viewed in plan view.

For various applications such as general lighting, display backlighting or indeed street lighting, light sources with a comparatively wide emission pattern are required. A half-value angle width of the light intensity distribution is then in particular at least 120°. The emission pattern preferably has a light intensity peak at large angles, i.e. specifically in an angular range of between 60° and 70°. Such an emission pattern is achievable with a semiconductor component described here.

Another possible way of achieving such an emission pattern is to use specially shaped lenses, which are curved concavely in a central region and convexly in a peripheral region. Such lenses are however generally comparatively large and typically have a height of between 2 mm and 6 mm and a diameter of roughly 15 mm. Furthermore, the fitting of such a lens is relatively complex and therefore costly. Such lenses may be placed or directly injection-molded onto the semiconductor chip.

In the semiconductor component described here, such a lens is replaced by the optical plate. The optical plate is preferably a plate with on average plane-parallel main sides. The optical plate is relatively thin in comparison with a lens and has lateral dimensions which are of the order of magnitude of the semiconductor chip. Through the configuration and arrangement of the pattern elements, a space-saving optical plate may be achieved, with which it is possible to achieve the desired emission pattern with a peak intensity in the light intensity distribution in particular at angles >50°.

According to at least one embodiment, the pattern elements have a refractive and/or reflective action. The pattern elements do not however constitute image-forming optical elements and the optical plate does not have a focal length, unlike in the case of convergent lenses and indeed diffusing lenses. Likewise, the pattern elements do not form an optically contiguous pattern, unlike in the case of a Fresnel lens. In other words, the optical plate is not a lens.

According to at least one embodiment, the optical plate comprises first pattern elements. The first pattern elements have a reflective action with regard to radiation generated in the semiconductor component. It is possible for the first pattern elements additionally to have a light-diffusing action, but primarily the function of the first pattern elements is to reflect radiation.

According to at least one embodiment, the optical plate comprises second pattern elements. The second pattern elements have a refractive and thus light-diffusing action. Any reflective action of the second pattern elements is preferably only secondary. In particular, the second pattern elements are brought about by surface patterning of the optical plate.

According to at least one embodiment, the first pattern elements are mounted in a central region of the top of the optical plate. The central region is for example circular. When viewed in plan view, the central region preferably covers the main radiation side of the semiconductor chip completely and without gaps.

According to at least one embodiment, the second pattern elements are mounted in a peripheral region of the top of the optical plate. When viewed in plan view, the peripheral region preferably surrounds the central region. The peripheral region preferably forms a single, contiguous area. The central region and the peripheral region may adjoin one another directly.

According to at least one embodiment, the first pattern elements are formed by particles with a reflective action. These particles are preferably embedded in a matrix material. A difference in refractive index between the reflectively acting particles and the matrix material is preferably at least 0.2 or 0.4 or 0.5. The reflective action of the first pattern elements arises in particular as a result of the jump in refractive index towards the matrix material and/or towards a base member of the optical plate.

According to at least one embodiment, the particles which form the first pattern elements are distributed uniformly and/or randomly in the matrix material in the central region. Alternatively it is possible for the first pattern elements to be arranged regularly.

According to at least one embodiment, the second pattern elements are formed by holes in or raised portions on the top. The holes or the raised portions are shaped for instance from the base member of the optical plate. At the second pattern elements there is preferably precisely just one jump in refractive index, namely between the optical plate and the surrounding environment of the optical plate on a side remote from the semiconductor chip.

According to at least one embodiment, the optical plate comprises an average reflectivity in the central region for radiation generated in the semiconductor component of at least 40% or 50% or 60% and/or of at most 90% or 85% or 75%. Alternatively or in addition, the transmissivity in the central region for the radiation generated in the semiconductor component is at least 15% or 20% or 30% and/or at most 80% or 70% or 60%. In other words, the central region is comparatively opaque. In the peripheral region, on the other hand, reflectivity is preferably only low and is for example at most 20%. Transmissivity in the peripheral region is preferably high and is for example at least 80% or 90%.

According to at least one embodiment, the semiconductor chip in the recess rests form-fittingly against the potting body. For example, the potting body is molded onto the semiconductor chip. Between chip side faces of the semiconductor chip and the potting body there is then no further material and the chips side faces touch the potting body and directly adjoin the potting body. It is possible for the chip side faces to rest directly against the potting body over their entire surface and to be completely covered by a material of the potting body. The main radiation side is preferably free of any potting body material.

According to at least one embodiment, a conversion element is located between the semiconductor chip and the optical plate. The conversion element is configured to convert some or all of the radiation generated by the semiconductor chip when in operation into radiation of another wavelength. The conversion element is for example a ceramic plate or a silicone plate, to which one or more luminescent materials have been added.

According to at least one embodiment, the conversion element is mounted directly on the main radiation side of the semiconductor chip. Directly may mean that the conversion element and the semiconductor chip touch or that nothing but a connecting means for attaching the conversion element to the semiconductor chip is located between the semiconductor chip and the conversion element.

According to at least one embodiment, the conversion element is in direct contact with the optical plate. The optical plate and the conversion element then touch or there is merely a connecting means such as an adhesive therebetween.

According to at least one embodiment, the conversion element adjoins the potting body in a lateral direction, i.e. in a direction parallel to the main radiation side. The potting body and the conversion element then touch at side faces of the conversion element. In particular, the potting body extends in the main emission direction at least as far as a side of the conversion element remote from the semiconductor chip.

According to at least one embodiment, the optical plate rests directly on the potting body, such that the potting body and the optical plate touch or such that there is merely a connecting means therebetween. Preferably, when viewed in plan view the optical plate lies on the potting body and around the semiconductor chip.

According to at least one embodiment, the optical plate, when viewed in plan view, is a round, in particular a circular plate. Alternatively it is possible for the optical plate to have a square or rectangular basic shape, wherein an optically active region of the optical plate is then preferably rotationally symmetrical in shape.

According to at least one embodiment, the optical plate has an axis of symmetry. Furthermore, the main radiation side preferably comprises an axis of symmetry, wherein electrical connecting means for energizing the semiconductor chip may be disregarded when determining the axis of symmetry. The axes of symmetry of the optical plate and of the main radiation side, which are oriented in a direction perpendicular to the main radiation side, preferably extend congruently, in particular with a tolerance of at most 10% or 5% of the edge length of the semiconductor chip.

According to at least one embodiment, the pattern elements of the optical plate are arranged rotationally symmetrically with regard to the axis of symmetry of the optical plate. The pattern elements are then arranged for instance in circles around a point of intersection of the axis of symmetry with the top of the optical plate.

According to at least one embodiment, a surface density of the pattern elements on the top of the optical plate decreases in a direction away from the axis of symmetry, i.e. outwards. The decrease is preferably monotonic or strictly monotonic. The decrease corresponds to a 1/x dependence or an e^{-x} dependence. Alternatively it is possible for the pattern elements to be distributed uniformly on the top, wherein this may apply to the entire top or the central region and/or the peripheral region. It is thus possible for the pattern elements to be distributed uniformly for instance in the central region and for a density to decrease outwards in the peripheral region.

According to at least one embodiment, the pattern elements are arranged regularly. This may be achieved for example by a stamping method or a printing method during production of the pattern elements. It is also possible for the pattern elements to be arranged at least in part randomly and/or irregularly on the top.

According to at least one embodiment, the pattern elements each have the same cross-sectional shape, in a direction perpendicular to the main radiation side. For example, the pattern elements have a triangular cross-sectional shape and take the form of cones, pyramids or prisms. It is likewise possible for the pattern elements to be cross-sectionally trapezoidal in shape and for instance to be embodied by truncated pyramids or truncated cones.

According to at least one embodiment, boundary faces of the pattern elements form an angle with a plane defined by the main radiation side of the semiconductor chip which is at least 50° or 60° or 65° and/or at most 80° or 75° or 70°. It is possible for the pattern elements, when viewed in cross-section, in each case to have an axis of symmetry which is oriented perpendicular to the main radiation side.

According to at least one embodiment, the top of the optical plate is a radiation exit side of the semiconductor component. In other words, the optical plate then at the same time also forms a cover plate for the semiconductor component.

According to at least one embodiment, a bottom of the optical plate facing the semiconductor chip is planar and/or smooth and thus has no pattern elements.

According to at least one embodiment, the semiconductor chip and potting body are mounted on a carrier top of a carrier. The carrier is for example a printed circuit board or a lead frame. The carrier may be the component mechanically bearing the semiconductor component. It is possible for the carrier to comprise electrical conductor tracks for connection of the semiconductor chip. Alternatively, it is possible for conductor tracks to be mounted in or on the potting body.

According to at least one embodiment, the matrix material for the first pattern elements is a silicone, an epoxide or a silicone-epoxide hybrid material. The first pattern elements are then preferably formed from a metal oxide such as titanium dioxide or aluminum oxide. A difference in refractive index between a material of the pattern elements and the matrix material is preferably at least 0.2. A thickness of the matrix material may be at least 0.25 mm or 0.4 mm and/or at most 2 mm or 1.5 mm or 1.0 mm.

According to at least one embodiment, the central region comprises a diameter which is at least 1.6 times or 1.8 times and/or at most 3.5 times or 2.5 times the edge length of the semiconductor chip. If the central region is not circular in plan view, an average diameter should be used rather than the diameter.

According to at least one embodiment, a diameter or an average diameter of the optical plate is at least five times or seven times and/or at most 15 times or twelve times or ten times the edge length of the semiconductor chip. Alternatively or in addition, the thickness of the optical plate is at least 1.4 times or 1.6 times or 1.8 times and/or at most 3.0 times or 2.5 times or 2.0 times the edge length of the semiconductor chip.

According to at least one embodiment, the pattern elements or the first pattern elements have an average diameter or an average edge length of at least 250 nm or 400 nm and/or of at most 5 μm or 2 μm or 1 μm. The average diameter may be an average size of the particles constituting the first pattern elements.

According to at least one embodiment, the pattern elements or the second pattern elements on the top of the optical plate, when viewed in plan view, have an average edge length of at least 0.5 μm or 0.75 μm and/or of at most 5 μm or 3 μm or 1.5 μm. It is possible for the first and/or the second pattern elements or the pattern elements on the top to be densely packed, such that at least 80% or 90% or 98% of the top is covered by the corresponding pattern elements.

According to at least one embodiment, the pattern elements have an average size of at least 0.3 μm or 0.5 μm. Alternatively or in addition, the average pattern size is at most 10 μm or 5 μm or 3 μm. The stated values apply in particular when viewed in plan view onto the top of the optical plate.

According to at least one embodiment, the optical plate and/or are the pattern elements or the second pattern elements are shaped from a transparent, radiation-transmissive material. For example, the optical plate and/or the pattern elements are shaped from a glass, a polycarbonate, a polyacrylate, a polymethyl methacrylate, a silicone or an epoxide or comprise one or more of these materials.

An optoelectronic semiconductor component described here is explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the figures:

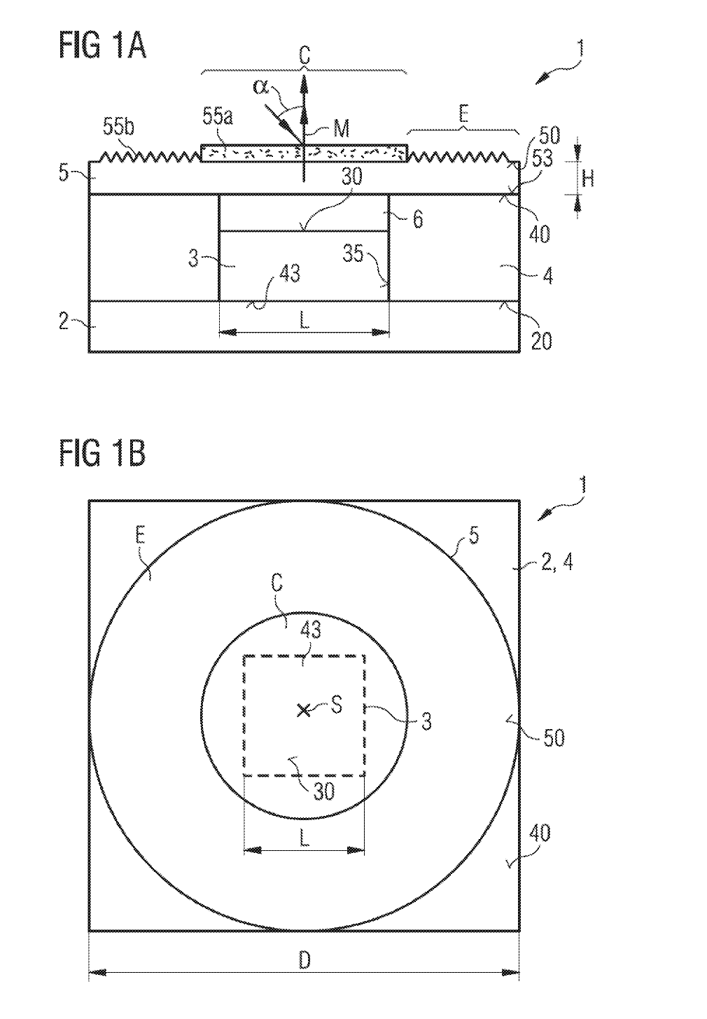

FIGS. 1 to 7 show schematic sectional representations and schematic plan views of exemplary embodiments of optoelectronic semiconductor components described here, and

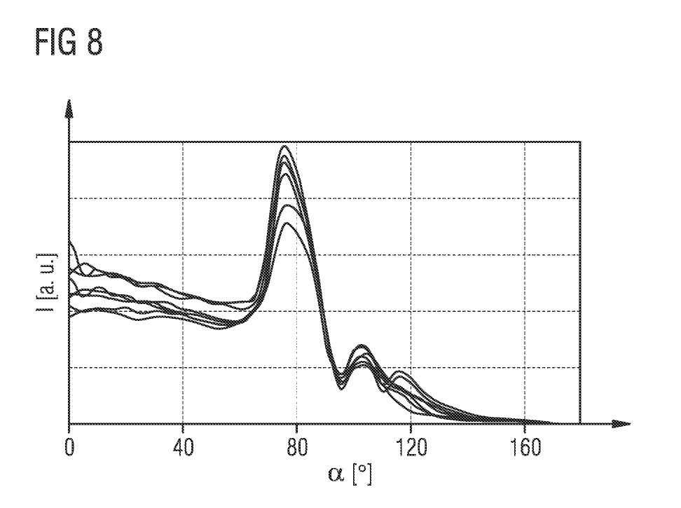

FIG. 8 is a schematic representation of an intensity as a function of a transmission angle.

FIG. 1A is a schematic sectional representation and FIG. 1B is a schematic plan view of an exemplary embodiment of an optoelectronic semiconductor component 1. The semiconductor component 1 comprises a carrier 2 with a carrier top 20. An optoelectronic semiconductor chip 3, for instance an LED, is mounted on the carrier 2. A main radiation side 30 of the semiconductor chip 3 is remote from the carrier 2. A conversion element 6 is applied to the main radiation side 30 for at least partial radiation conversion. By combining the semiconductor chip 3 and the conversion element 6, white light may for example be generated.

The semiconductor chip 3 and the conversion element 6 are located completely in a recess 43 in a potting body 4. The potting body 4 is produced in particular after mounting of the semiconductor chip 3 and the conversion element 6. The potting body 4 preferably terminates flush with a top of the conversion element 6 remote from the semiconductor chip 3, in a main emission direction M of semiconductor chip 3. The potting body 4 is in contact with the chip side faces 35 of the semiconductor chip 3 over their entire surface. The recess 43 and the semiconductor chip 3 have an edge length L. The main emission direction M is that direction in which the semiconductor chip 3 emits with the greatest intensity. In particular, the main emission direction M is oriented perpendicular to the main radiation side 30.

An optical plate 5 is mounted on the conversion element 6 and the potting body 4. The optical plate 5 completely covers the semiconductor chip 3 when viewed in plan view. The optical plate 5 comprises a central region C and a peripheral region E which completely surrounds the central region C. A thickness of the optical plate 5 is preferably at most 1 mm or at most 0.25 mm.

The optical plate 5 comprises a smooth bottom 53 and a top 50 remote from the semiconductor chip 3. First pattern elements 55a are mounted on the top 50 in the central region C. The first pattern elements 55a are formed by titanium dioxide particles with an average diameter of 500 nm, which are introduced in a proportion by volume of 40% into a silicone matrix with a refractive index of 1.4. The layer with the first pattern elements 55a has a thickness of 0.5 mm and a diameter which corresponds to 2.1 times the edge length L of the semiconductor chip. The matrix material with the first pattern elements 55a is applied to a base member of the optical plate 5.

In the peripheral region E second pattern elements 55b are mounted. The second pattern elements 55b are formed by pyramids, which are shaped on the top 50. These pyramids are formed from the same material as the base member of the optical plate 5 and produced from this base member, for instance using a nano printing method or an embossing method. Side faces of these pyramids form an angle of between 60° and 80° inclusive, in particular roughly 70°, with the main radiation side 30. The tips of the pyramids are arranged at a distance of 1 μm from one another and, when viewed in plan view, the pyramids have an edge length of 1 μm, such that the second pattern elements 55b are arranged densely on the top 50 in the peripheral region E. A material of the main body of the optical plate 5 is for example a plastic or a glass with a refractive index of 1.5. The optical plate has a diameter D, which corresponds to ten times the edge length L. A thickness H of the optical plate 5 is twice the edge length L. The edge length L is for example 1 mm.

The numerical values stated in the preceding paragraphs for the optical plate 5 and for the pattern elements 55a, 55b preferably apply with a tolerance of at most 50% or 25% or 10%.

Unlike in the illustration of FIG. 1B, it is possible for the entire semiconductor component 1 to be circular in shape. It is likewise possible for the optical plate 5 to have a square or rectangular basic shape and to be configured congruently to the potting body 4 and/or to the carrier 2. In this case, the central region C is moreover preferably rotationally symmetrical and circular, when viewed in plan view.

The semiconductor component 1 may be a “QFN”, or Quad Flat No-Lead, component. In particular, the semiconductor component 1 is surface-mountable. To simplify the illustration, electrical connection means, such as conductor tracks, through-vias or bonding wires respectively, are not shown. Also to simplify the illustration, the semiconductor component 1 illustrated comprises just one semiconductor chip 3, although a plurality of semiconductor chips 3 may likewise be present. It is also possible for additional semiconductor chips to be present, for instance to provide protection from damage by electrostatic discharges. Such further semiconductor chips are not shown.

In FIG. 8, an intensity I in arbitrary units, or a. u. for short, is plotted schematically for the exemplary embodiment according to FIG. 1 against an emission angle α. A maximum intensity I is emitted at an angle of roughly 75°. Over an angular range of roughly 0° to 60° the intensity I is approximately constant. Small proportions of the radiation also undergo backscattering and are emitted at angles >90°.

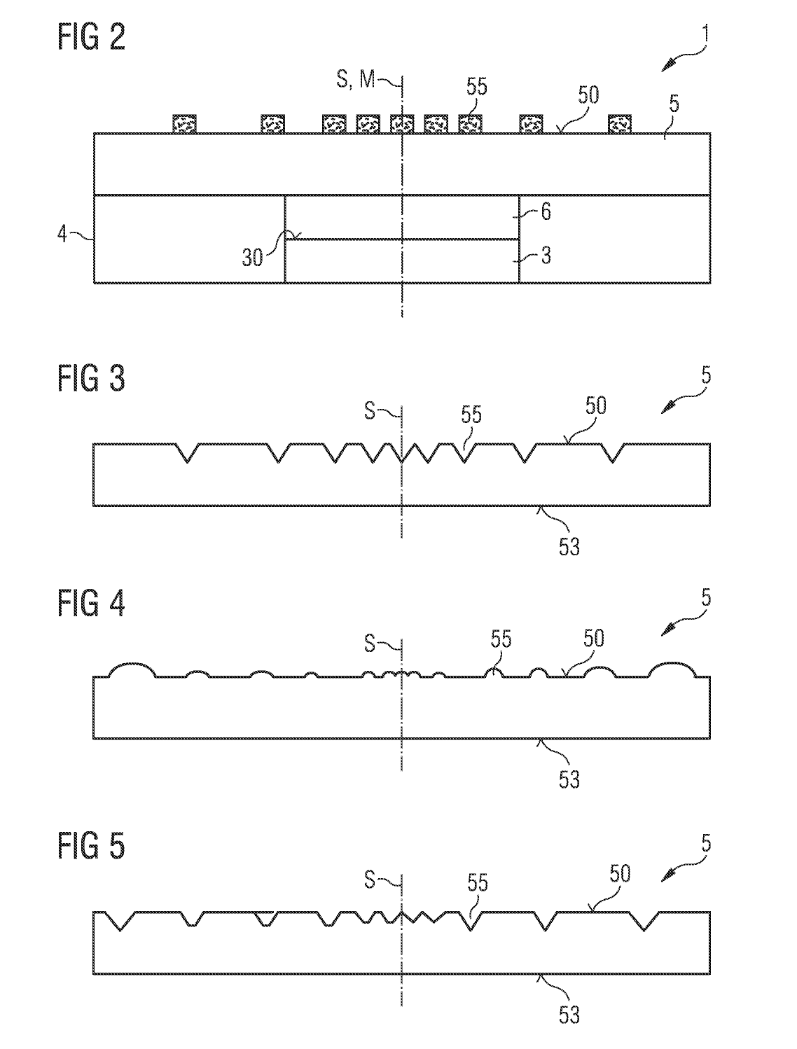

FIG. 2 shows a schematic sectional representation of a further exemplary embodiment. As in all the other exemplary embodiments, it is possible for the axes of symmetry S of the semiconductor chip 3 and the optical plate 5 to coincide. The axes of symmetry S are preferably oriented parallel to the main emission direction M.

Unlike in FIG. 1, the semiconductor component 1 as shown in FIG. 2 comprises just a single type of pattern elements 55, which are for instance printed on or applied by vapor deposition to the top 50 of the optical plate 5. The pattern elements 55 may be individual dots or circular tracks. The pattern elements 55 are for instance printed-on dots of a material with a refractive index which is different from a refractive index of the other constituents of the optical plate 5.

It is optionally possible for the pattern elements 55 to comprise a matrix material with scattering particles and/or reflective particles embedded therein. In a direction away from the axis of symmetry S a surface density of the pattern elements 55 on the top 50 decreases. Preferably, the pattern elements 55 are densely packed directly above the main radiation side 30 and only start to decrease in density in a peripheral region.

According to FIG. 3, the pattern elements 55 are all identically shaped and are embodied as recesses or holes in the top 50. The pattern elements 55 are triangular in shape when viewed in cross-section.

FIG. 4 shows that the pattern elements 55 are formed by semicircular raised portions when viewed in cross-section. It is optionally possible that, towards the outside, in a direction away from the axis of symmetry S, a surface density of the pattern elements 55 decreases and/or a size of the pattern elements 55 increases.

In the exemplary embodiment according to FIG. 5, the pattern elements 55 are formed by holes or recesses. A size of the pattern elements 55 may also decrease in a direction away from the axis of symmetry S, in contrast to what is shown in the drawing. It is not necessary for the pattern elements 55 to have an axis of symmetry when viewed in cross-section which is oriented parallel to the axis of symmetry S of the optical plate 5. For example, boundary faces of the pattern elements 55 facing the axis of symmetry S form a smaller or indeed a larger angle with the bottom 53 than boundary faces remote from the axis of symmetry S.

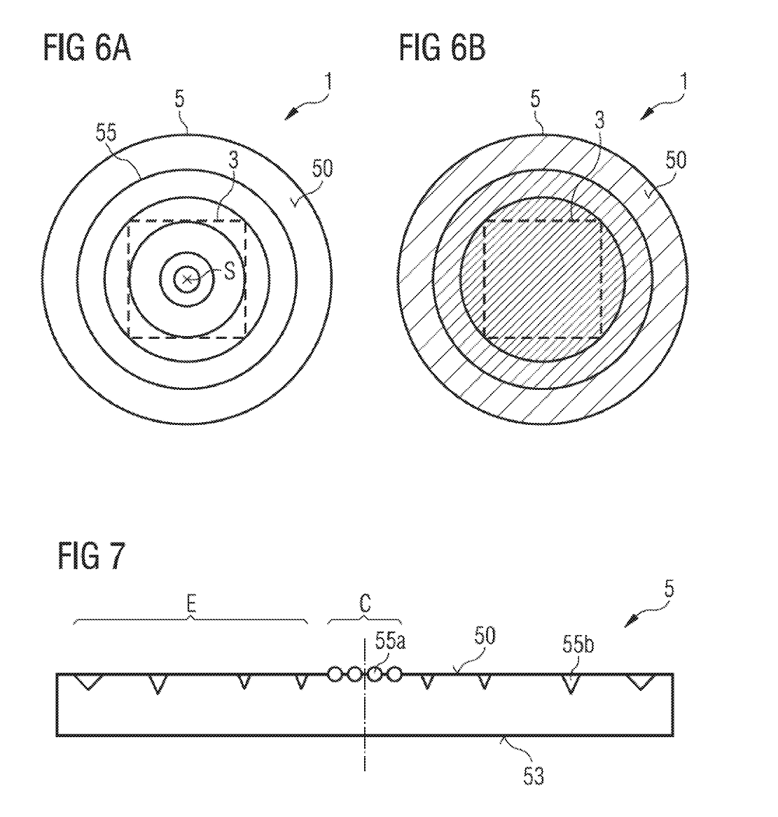

FIG. 6 shows plan views of exemplary embodiments of the semiconductor component 1. According to FIG. 6A, the pattern elements 55 take the form of annular patterns, which have an increasing distance from one another in a direction away from the axis of symmetry S.

In the exemplary embodiment according to FIG. 6B, the pattern elements 55 are randomly distributed and irregularly arranged. A hatching density on the top 50 symbolizes a density of the pattern elements 55. A surface density of the pattern elements 55 on the top 50 decreases outwards in steps. Unlike in the illustration, the surface density of the pattern elements 55 may also decrease outwards continuously.

In the exemplary embodiment according to FIG. 7, the first pattern elements 55a are formed by reflective particles on the top 50. The second pattern elements 55b are embodied by recesses or notches in the surface 50. Unlike in the illustration, the surface density of the second pattern elements 55b may be constant in the peripheral region E.

The optical plates 5 shown in FIGS. 3, 4, 5 and 7 may in each case be mounted on a semiconductor chip 3, as shown in FIG. 1, 2 or 6.

It is in particular possible for pattern elements 55 as illustrated in FIGS. 3 to 5 also to be used in the exemplary embodiment according to FIG. 1 in particular for the second pattern elements 55b. The same is true of the first pattern elements 55a of FIG. 7, which may also be used in exemplary embodiments according to FIG. 1.

The invention described here is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

This patent application claims priority from German patent application 10 2013 106 689.5, the disclosure content of which is hereby included by reference.

1. Optoelectronic semiconductor component having
a potting body with at least one recess,
at least one optoelectronic semiconductor chip for generating radiation, which is located in the recess and comprises a main radiation side with an edge length, and
at least one optical plate, which covers the recess and which is arranged downstream of the semiconductor chip in a main emission direction, wherein
the optical plate comprises a multiplicity of pattern elements on a top remote from the semiconductor chip,
the optical plate has a diameter which amounts to at least 1.5 times the edge length of the semiconductor chip,
the optical plate has a thickness which amounts to at least 0.1 times and at most 1.5 times the diameter,
the optical plate completely covers the main radiation side when viewed in plan view
the optical plate comprises first pattern elements and second pattern elements,
the first pattern elements have a reflective action and the second pattern elements have a diffusing action with regard to radiation emitted by the semiconductor chip,
the first pattern elements are mounted in a central region of the top and, when viewed in plan view, the central region completely covers the main radiation side,
the second pattern elements are mounted in a peripheral region of the top and the peripheral region surrounds the central region, when viewed in plan view, and
wherein the optical plate is a plate with on average plane-parallel main sides.

2. (canceled)

3. Optoelectronic semiconductor component according to claim 16,
wherein the first pattern elements have a reflective action and are applied to a base member of the optical plate and the second pattern elements have a refractive action and are shaped from the base member, and
wherein the optical plate is a plate with on average plane-parallel main sides.

4. Optoelectronic semiconductor component according to claim 1,
in which the first pattern elements are particles with a reflective action, which are embedded in a matrix material and are distributed uniformly in the matrix material in the central region, and
in which the second pattern elements are formed by holes in or by raised portions on the top.

5. Optoelectronic semiconductor component according to claim 1,
in which the optical plate comprises an average reflectivity in the central region for radiation generated in the semiconductor component of between 50% and 85% inclusive.

6. Optoelectronic semiconductor component according to claim 1,
in which the semiconductor chip in the recess rests form-fittingly against the potting body such that chip side faces of the semiconductor chip directly adjoin the potting body over their entire surface.

7. Optoelectronic semiconductor component according to claim 1,
in which a conversion element is located between the semiconductor chip and the optical plate, in each case directly adjacent, said conversion element being configured to convert some of the radiation generated by the semiconductor chip when in operation into radiation of another wavelength,
wherein the conversion element adjoins the potting body in a direction parallel to the main radiation side.

8. Optoelectronic semiconductor component according to claim 1,
in which the optical plate, when viewed in plan view, lies directly on the potting body, next to the semiconductor chip and around the semiconductor chip.

9. Optoelectronic semiconductor component according to claim 1,
in which, when viewed in plan view, the optical plate is a circular plate and axes of symmetry, extending perpendicular to the main radiation side, of the optical plate and of the semiconductor chip extend congruently.

10. Optoelectronic semiconductor component according to claim 9,
in which the pattern elements are arranged rotationally symmetrically around the axes of symmetry of the optical plate.

11. Optoelectronic semiconductor component according to claim 1,
in which, when viewed in plan view, a surface density of the pattern elements on the top of the optical plate decreases outwards in a direction away from the axes of symmetry.

12. Optoelectronic semiconductor component according to claim 1,
in which the pattern elements are arranged regularly and in each case have the same cross-sectional shape, in a direction perpendicular to the main radiation side.

13. Optoelectronic semiconductor component according to claim 16,
in which the pattern elements are triangular in shape when viewed in cross-section and boundary faces of the pattern elements are oriented at an angle of between 60° and 80° inclusive relative to a plane defined by the main radiation side.

14. Optoelectronic semiconductor component according to claim 1,
in which the top of the optical plate is a radiation exit side of the semiconductor component, wherein a bottom of the optical plate facing the semiconductor chip is planar in shape and wherein the semiconductor chip and the potting body are mounted on a carrier top of a carrier.

15. Optoelectronic semiconductor component according to claim 4,
in which
a difference in refractive index between the matrix material, which is a silicone, and a material of the first pattern elements, which is a metal oxide, amounts to at least 0.2 and the matrix material has a thickness of between 0.25 mm and 1.0 mm inclusive,
the edge length of the semiconductor chip is between 0.5 mm and 2.5 mm inclusive,
the central region has a diameter of between 1.6 times and 2.5 times the edge length inclusive,
the diameter of the optical plate is between seven times and fifteen times the edge length inclusive,
the thickness of the optical plate amounts to between 1.6 times and 2.5 times the edge length inclusive,
the first pattern elements have an average diameter of between 250 nm and 1 μm inclusive,
the second pattern elements, when viewed in plan view, are densely packed on the top over the entire peripheral region and have an average diameter or an average edge length of between 0.75 μm and 3 μm inclusive, and
the optical plate and the second pattern elements consist of a transparent material, selected from the group comprising glass, polycarbonate and polyacrylate, or comprise at least one of these materials.

16. Optoelectronic semiconductor component having
a potting body with at least one recess,
at least one optoelectronic semiconductor chip for generating radiation, which is located in the recess and comprises a main radiation side with an edge length, and
at least one optical plate, which covers the recess and which is arranged downstream of the semiconductor chip in a main emission direction, wherein
the optical plate comprises a multiplicity of pattern elements on a top remote from the semiconductor chip,
the optical plate has a diameter which amounts to at least 1.5 times the edge length of the semiconductor chip,
the optical plate has a thickness which amounts to at least 0.1 times and at most 1.5 times the diameter, and
the optical plate completely covers the main radiation side when viewed in plan view.
